(19) United States
(12) Patent Application Publication
(10) Pub. No.: US 2007/0126525 A1
(43) Pub. Date: Jun. 7, 2007

(54) Dual path attenuation system

(76) Inventor: Dean B. Nicholson, Windsor, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/291,683

(22) Filed: Dec. 1, 2005

(51) Int. Cl. H03H 7/24; H03H 7/25; H01P 1/22

(52) U.S. Cl. 333/81 R

(57) ABSTRACT

A dual path attenuation system includes an ALC system, a through signal path, an attenuation signal path, and a non-terminated input switch and a non-terminated output switch that alternatively couple one of the through signal path and the attenuation signal path between an input and an output. The ALC system adjusts the amplitude of an applied input signal over an adjustment range to provide an amplitude-leveled output signal. The non-terminated input switch and non-terminated output switch couple the through signal path between the input and the output when the amplitude-leveled signal has an amplitude above a designated threshold within the adjustment range, and couple the attenuation signal path between the input and the output when the amplitude-leveled signal has an amplitude that is below the designated threshold.

### CROSS-REFERENCE To RELATED APPLICATIONS

The present application is related to concurrently filed, co-pending, and commonly assigned U.S. patent application No. ______, Attorney Docket Number 10060051-1, entitled “Electronic Microcircuit Having Internal Light Enhancement”, the disclosure of which is hereby incorporated herein by reference.

### BACKGROUND OF THE INVENTION

Step attenuators are included in signal sources, network analyzers, multifunction testers, and other instruments and systems. In a typical instrument, a step attenuator is included outside the feedback loop of an automatic level control (ALC) system. The step attenuator adjusts the amplitude of the electrical signals in discrete attenuation steps, whereas the ALC system provides continuous, or vernier, control of the amplitude of the signals.

In one type of step attenuator, attenuation circuits are mechanically selected or switched. This type of step attenuator can accommodate high power signals without adding distortion to the signals that are applied to the step attenuator. However, these mechanically-switched step attenuators have the disadvantages of large physical size and low switching speeds.

In another type of step attenuator, the attenuation circuits are electronically switched using PIN diodes. This type of step attenuator is physically compact and can achieve high switching speeds. However, these PIN-switched step attenuators add distortion to applied signals that have low frequencies, for example frequencies that are below approximately 1 MHz.

In an integrated circuit (IC) step attenuator, attenuation circuits are implemented and switched using field effect transistors (FETs). These IC step attenuators are physically compact and have high switching speed. At low power levels, the IC step attenuators have low distortion over a wide frequency range. However, the IC step attenuators have the disadvantage of introducing high levels of distortion to applied signals that have high power levels, due to the inherent nonlinearities of the FETs within the IC step attenuators.

Accordingly, there is a need for a step attenuator that has the high switching speed, the physical compactness, and the wide operating frequency range of the FET-switched step attenuator, with the benefits of low distortion and accommodation of high power signals that are provided by the mechanically-switched step attenuator.

### BRIEF DESCRIPTION OF THE DRAWINGS

FIG. 1 shows an example of a dual path attenuation system according to embodiments of the present invention.

FIG. 2 shows an example of a dual signal path attenuator included in the dual path attenuation system according to embodiments of the present invention.

FIG. 3 shows an example of a circuit board including the dual path attenuation system according to embodiments of the present invention.

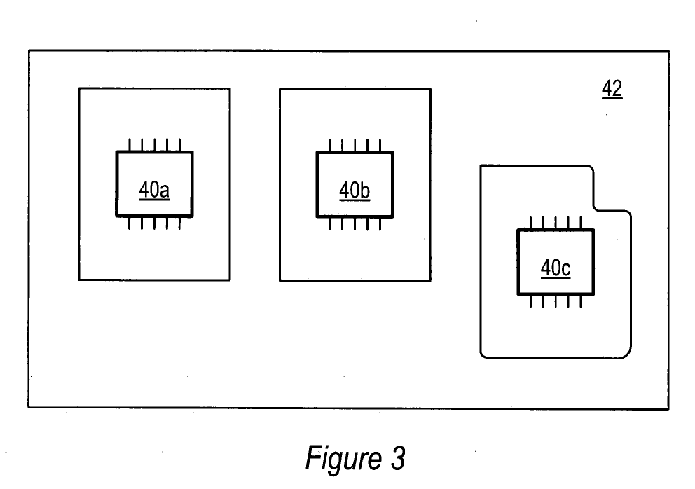

### DETAILED DESCRIPTION

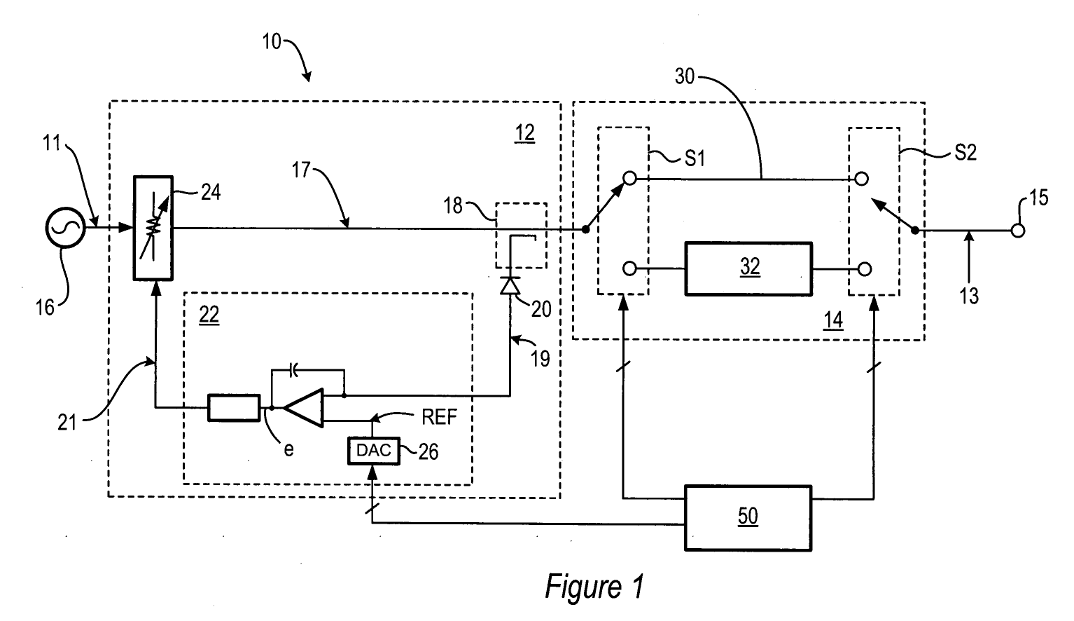

FIG. 1 shows one example of a dual path attenuation system 10 according to embodiments of the present invention, including an automatic level control (ALC) system 12 and a dual signal path attenuator 14. The dual path attenuation system 10 provides for adjustment of the amplitude of an applied input signal 11 and provides an amplitude-leveled output signal 13 at an output port 15 of the dual signal path attenuator 14. In this example, the applied input signal 11 is provided to the dual path attenuation system 10 by a signal source 16, including any type of network, circuit, device, element, or system suitable for generating or otherwise providing electrical signals.

U.S. Pat. No. 4,263,560 and U.S. Pat. No. 5,661,442 disclose two examples of the many types of ALC systems 12 that are suitable for inclusion in the dual path attenuation system 10. The ALC system 12, shown in FIG. 1, includes a signal coupler 18, a level detector 20, level control circuitry 22, and a variable attenuator 24 that form a feedback control loop. The signal coupler 18 includes a distributed coupler, a power divider, a resistive bridge, or other circuit or system suitable for coupling a portion of a signal 17, provided to the dual signal path attenuator 14, to the level detector 20. The level detector 20 typically includes a detector diode, power sensor, or other device, element or system suitable for providing a detected signal 19 that corresponds to the amplitude of the signal 17. Amplitude can be represented by the magnitude, voltage, current, or power of the signal 17, or any other suitable indicator of the level of the signal 17. The variable attenuator 24 within the ALC system 12 includes a PIN diode attenuator, a FET attenuator, a variable gain amplifier, or any other device, element or system suitable for adjusting the amplitude of the applied input signal 11 in response to a control signal 21 provided by the level control circuitry 22.

In a balanced operating state of the ALC system 12, the detected signal 19 provided by the level detector 20 corresponds to the amplitude of the signal 17 that is applied to the input of the dual signal path attenuator 14. The level control circuitry 22 receives the detected signal 19, compares the detected signal 19 to a reference signal REF, and generates an error signal e based on the comparison. The error signal e is then conditioned to provide the control signal 21 that drives the variable attenuator 24. The ALC system 12 has sufficient gain to enable the level control circuitry 22 to adjust the attenuation of the variable attenuator 24 to minimize the error signal e. Minimizing the error signal e amplitude-levels the signal 17 and enables the amplitude of the signal 17 to be adjusted according to adjustments the reference signal REF.

In a balanced operating state, the ALC system 12 provides vernier adjustment of the amplitude of the signal 17. The vernier amplitude adjustment is typically continuous within the resolution of the DAC 26, or other device or system, used to set the reference signal REF within the level control circuitry 22 of the ALC system 12. The dual signal path attenuator 14 receives the signal 17 and provides stepped attenuation of the amplitude of the output signal 13, in addition to the vernier adjustment of the amplitude that is provided by the ALC system 12. The combined vernier adjustment and stepped attenuation of the amplitude of the output signal 13 enables the amplitude of the output signal 13 to be adjusted continuously over a wide adjustment range.

Typically, the ALC system 12 can also operate in an open loop state wherein the signal 17 is not amplitude-leveled, or in an externally leveled state wherein a signal coupler and level detector external to those of the ALC system 12 shown in FIG. 1 are included the dual path attenuation system 10 to form a feedback loop.

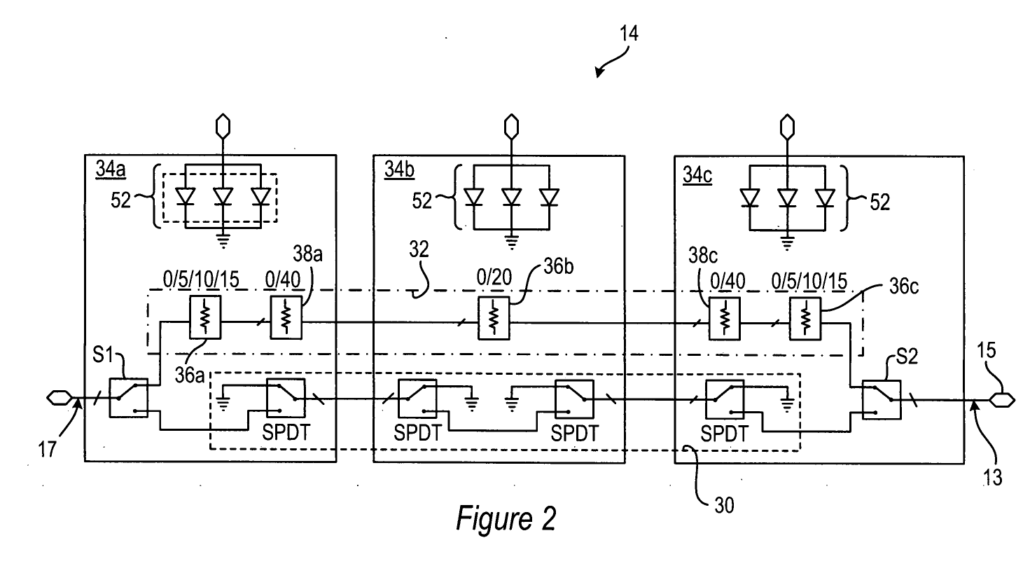

The dual signal path attenuator 14 (shown in FIG. 2) includes a through signal path 30, an attenuation signal path 32, and an input switch S1 and an output switch S2 that alternatively couple the through signal path 30 and the attenuation signal path 32 between the input of the dual signal path attenuator 14 and the output port 15. The input switch S1 and the output switch S2 in the dual signal path attenuator 14 are non-terminated, that is, the input switch S1 and the output switch S2 do not provide for matched termination of switch paths that are not selected.

In the example of the dual signal path attenuator 14 shown in FIG. 2, the dual signal path attenuator 14 is implemented in three cascaded stages 34a, 34b, 34c to achieve an attenuation adjustment range of 130 dB in 5 dB attenuation steps. The first stage 34a includes the input switch S1 as a single pole-double throw (SPDT) switch, implemented using FET switches. In the first stage 34a, the attenuation signal path 32 includes two cascaded integrated chip (IC) step attenuators 36a, 38a. The IC step attenuator 36a provides 5 dB attenuation steps to alternatively achieve attenuation of 0 dB, 5 dB, 10 dB, and 15 dB. The IC step attenuator 38a provides one 40 dB attenuation step to alternatively achieve attenuation of 0 dB and 40 dB. The combination of the IC step attenuators 36a, 38a provides the first stage of the attenuation signal path 32 with an attenuation adjustment range of 55 dB. In the second stage, the attenuation signal path 32 includes one IC step attenuator 36b. The IC step attenuator 36b provides one 20 dB attenuation step to alternatively achieve attenuation of 0 dB and 20 dB, to achieve an attenuation adjustment range of 20 dB. The third stage 34c includes the output switch S2 as a single pole-double throw (SPDT) switch, implemented using FET switches. In the third stage 34c, the attenuation signal path 32 also includes two cascaded integrated chip (IC) step attenuators 36c, 38c. The IC step attenuator 36c provides 5 dB attenuation steps to alternatively achieve attenuation of 0 dB, 5 dB, 10 dB, and 15 dB. The IC step attenuator 38c provides one 40 dB attenuation step to alternatively achieve attenuation of 0 dB and 40 dB. The combination of the IC step attenuators 36c, 38c provides the third stage of the attenuation signal path 32 with an attenuation adjustment range of 55 dB. The AGILENT TECHNOLOGIES, INC. model E4438C ESG Vector Signal Generator includes IC step attenuators that are suitable for inclusion in the attenuation signal path 32 of the dual signal path attenuator 14.

According to one embodiment of the dual path attenuation system 10, each of the cascaded stages 34a, 34b, 34c is housed in a corresponding laminate or ceramic package 40a, 40b, 40c. The packages 40a, 40b, 40c are suitable for mounting on a substrate 42 using surface mount technology (SMT) or printed circuit board (PCB) technology. According to alternative embodiments of the dual path attenuation system 10, the dual signal path attenuator 14 is housed in a shielded microcircuit package or other suitable package. The three cascaded stages 34a, 34b, 34c housed in the packages 40a, 40b, 40c in the dual signal path attenuator 14 shown in FIG. 2 provide sufficient signal isolation to achieve the 130 dB step attenuation adjustment range. In alternative examples of the dual signal path attenuator 14, the number of cascaded stages, the attenuation adjustment range achieved within each of the stages, the size of the attenuation steps, and the total attenuation adjustment range can have alternative designations based on the performance parameters of the system or instrument within which the dual path attenuation system 10 is included.

In the example of the dual signal path attenuator 14 shown in FIG. 2, the IC step attenuators and the included input switch S1 and output switch S2 are implemented using GaAs integrated circuits that are illuminated by one or more LEDs 52. The one or more LEDs 52 prevent slow tails or other switching transients during transitions between attenuation states in the attenuation signal path 32 of the dual signal path attenuator 14 that are associated with gate lag effects in GaAs FETs. Typically, the LEDs 52 directly illuminate the IC step attenuators. Alternatively, the light from the LEDs 52 is reflected from the lid of the ceramic packages, or directed to the IC step attenuators using lenses. In one example, three high-intensity surface mount LEDs 52 are included in each of the packages 40a, 40b, 40c to provide the dual signal path attenuator 14 with a switching time between attenuation steps that is less than 15 microseconds and a switching time between the through signal path 30 and the attenuation signal path 32 that is also less than 15 microseconds.

The through signal path 30 and the attenuation signal path 32 of the dual signal path attenuator 14 are alternatively selected under the control of a processor 50 (shown in FIG. 1), via the input switch S1 and the output switch S2. The processor 50 also controls the amplitude of the output signal 13 via the DAC 26 in the level control circuitry 22, and the IC step attenuators in the attenuation signal path 32. Typically, the through signal path 30 is selected when the output signal 13 is set, specified, or otherwise designated, to have an amplitude that is above a designated threshold. The attenuation signal path 32 is selected when the output signal 13 is set, specified, or otherwise designated, to have an amplitude that is below the threshold. According to one embodiment of the dual path attenuation system 10, the threshold is designated based on the difference between the amplitude adjustment range of the ALC system 12 and the minimum attenuation step size achievable by the attenuation path 32. For example, when the ALC system 12 provides a 15 dB adjustment range and the minimum attenuation step size is 5 dB, the threshold is designated so that the through signal path 30 is selected when the output signal 13 is within the top 10 dB of the power range of the output signal 13, and the attenuation signal path 32 is selected when the output signal 13 is below 10 dB from the top of the power range of the output signal 13.

The threshold can be frequency dependent to accommodate for frequency dependence of the insertion loss of the signal path between the signal coupler 18 and the output port 15, or for the dependence of the adjustment range of the ALC system 12 on the frequency of the output signal 13.

The threshold can also be designated based on the distortion requirements for the output signal 13. For example, the through signal path 30 can be selected when the output signal 13 has sufficiently high power to introduce an unacceptable level of distortion in the attenuation signal path 32.

While the embodiments of the present invention have been illustrated in detail, it should be apparent that modifications and adaptations to these embodiments may occur to one skilled in the art without departing from the scope of the present invention as set forth in the following claims.

1. A dual path attenuation system, comprising:
a through signal path;
an attenuation signal path;
a non-terminated input switch and a non-terminated output switch alternatively coupling one of the through signal path and the attenuation signal path between an input and an output; and
an ALC system adjusting the amplitude of an applied input signal over an adjustment range to provide an amplitude-leveled signal, wherein the non-terminated input switch and the non-terminated output switch couple the through signal path between the input and the output when the amplitude-leveled signal has an amplitude above a designated threshold within the adjustment range, and wherein the non-terminated input switch and the non-terminated output switch couple the attenuation signal path between the input and the output when the amplitude-leveled signal has an amplitude that is below the designated threshold.

2. The dual path attenuation system of claim 1 wherein the attenuation signal path provides step attenuation to the amplitude-leveled signal when the non-terminated input switch and the non-terminated output switch couple the attenuation signal path between the input and the output.

3. The dual path attenuation system of claim 2 wherein the threshold is designated based on the difference between the adjustment range and a minimum step size of the step attenuation provided by the attenuation signal path.

4. The dual path attenuation system of claim 1 wherein the non-terminated input switch and the non-terminated output switch are each implemented using one or more FETs.

5. The dual path attenuation system of claim 1 wherein the attenuation path includes at least one IC step attenuator.

6. The dual path attenuation system of claim 5 wherein the at least one IC step attenuator includes three cascaded stages, each stage housed in a corresponding package.

7. The dual path attenuation system of claim 6 wherein the first stage and third stage of the three cascaded stages each provide for 55 dB of attenuation, and the second stage of the three cascaded stages provides for 20 dB of attenuation.

8. The dual path attenuation system of claim 6 wherein the corresponding package housing each of the three cascaded stages is ceramic.

9. The dual path attenuation system of claim 6 wherein the corresponding package housing each of the three cascaded stages is laminate.

10. The dual path attenuation system of claim 7 wherein the first stage and the third stage each include a first IC step attenuator providing a 15 dB attenuation range in 5 dB attenuation steps, and a second IC step attenuator providing a 40 dB attenuation range in a 40 dB attenuation step.

11. The dual path attenuation system of claim 10 wherein the second stage includes an IC step attenuator providing a 20 dB attenuation range in a 20 dB step.

12. A dual path attenuation system, comprising:
a through signal path;
an attenuation signal path;
a first non-terminated switch and a second non-terminated switch alternatively coupling one of the through signal path and the attenuation signal path between an input and an output; and
an ALC system adjusting the amplitude of an applied input signal over an adjustment range to provide an amplitude-leveled signal, wherein the first non-terminated switch and second non-terminated switch couple the through signal path between the input and the output when the amplitude-leveled signal has an amplitude above a designated threshold within the adjustment range, and wherein the first non-terminated switch and second non-terminated switch couple the attenuation signal path between the input and the output when the amplitude-leveled signal has an amplitude that is below the designated threshold.

13. The dual path attenuation system of claim 12 wherein the first non-terminated switch, the second non-terminated switch and the attenuation signal path are implemented on one or more GaAs integrated circuits.

14. The dual path attenuation system of claim 12 wherein the attenuation signal path provides step attenuation to the amplitude-leveled signal when the first non-terminated switch and the second non-terminated switch couple the attenuation signal path between the input and the output.

15. The dual path attenuation system of claim 13 wherein the attenuation signal path provides step attenuation to the amplitude-leveled signal when the first non-terminated switch and the second non-terminated switch couple the attenuation signal path between the input and the output.

16. The dual path attenuation system of claim 13 wherein the one or more GaAs integrated circuits are illuminated by one or more LEDs.

17. The dual path attenuation system of claim 16 wherein the one or more GaAs integrated circuits are housed in a cascaded series of ceramic packages.

18. The dual path attenuation system of claim 16 wherein the one or more GaAs integrated circuits are housed in a cascaded series of laminate packages.
